(19) United States
(12) Patent Application Publication
(10) Pub. No.: US 2025/0258982 A1
(43) Pub. Date: Aug. 14, 2025

(54) METHOD FOR CREATING ADHERENCE CURVE MODELS FROM GAS DATA ACQUIRED DURING DRILLING USING MACHINE LEARNING

(71) Applicants: PETRÓLEO BRASILEIRO S.A. – PETROBRAS, Rio de Janeiro (BR); PONTIFÍCIA UNIVERSIDADE CATÓLICA DO RIO DE JANEIRO, Rio de Janeiro (BR)

(72) Inventors: Gil Marcio AVELINO SILVA, Rio de Janeiro (BR); Moises Henrique PEREIRA, Rio de Janeiro (BR); Frederico Custodio VIEIRA DOS SANTOS, Rio de Janeiro (BR); Francisco Fábio DE ARAÚJO PONTE, Rio de Janeiro (BR); Sarah BARRÓN TORRES, Rio de Janeiro (BR); Joelson Vialle MATHIAS DA SILVA, Rio de Janeiro (BR); Fernando PELLON DE MIRANDA, Rio de Janeiro (BR); Italo DE OLIVEIRA MATIAS, Rio de Janeiro (BR); Rafael Barbosa NASSER, Rio de Janeiro (BR); Gustavo ROBICHEZ DE CARVALHO, Rio de Janeiro (BR)

(21) Appl. No.: 19/017,734

(22) Filed: Jan. 12, 2025

(30) Foreign Application Priority Data
Feb. 8, 2024 (BR) 1020240026578

(51) Int. Cl. G06F 30/28

(52) U.S. Cl. CPC G06F 30/28

(57) ABSTRACT

The present disclosure addresses a method that aims at improving the process of analyzing and interpreting Gas data, with the creation of adherence curves from Advanced Gas data, based on their similarity with PVT samples from wells completed from mathematical routines using Machine Learning. The implemented approach aims at contributing significantly to geochemical research based on the greater reliability given to the analysis and interpretation of Gas data—since estimates of associated errors and/or deviations will be addressed to—, especially by increasing the efficiency of decisions and timing required by operational activities, which directly affects the costs related to drilling and well risks.

### FIELD OF THE DISCLOSURE

The present disclosure includes embodiments of a method for creating adherence curve models from Advanced Gas (GAV) data-acquired during drilling-by employing machine learning algorithms (e.g., B-Spline, Ridge, Kernel Ridge and Gradient Boosting Regressor). This process required the development of similarity analyses between these GAV data and PVT samples (subjected to variations in pressure, volume and temperature within a controlled environment and with the appropriate equipment to modify their original state) from completed wells, employing mathematical routines for multivariate data analyses.

### DESCRIPTION OF THE STATE OF THE ART

In the oil and gas industry, consolidated technologies such as Artificial Intelligence (AI) assist geologists, geophysicists, engineers and managers by optimizing the extraction of their capabilities, tools and internal applications. These technologies enhance the collective intelligence, positively impacting decision-making by providing greater assertiveness, precision and safety.

AI is a branch of computer science focused on the development of software capable of simulating human cognitive abilities, including logical reasoning, perception, decision-making and problem-solving. This field encompasses a wide range of methods, algorithms and techniques that can make an application intelligent in the human sense of the word.

Within the scope of AI, Machine Learning (ML) stands out as an essential component. This field of study enables computers to learn specific tasks through training and data classification, allowing their subsequent application, without the need for an explicit programming. ML represents a powerful approach for data analysis, modeling, and visualization, and its use has been rapidly increasing in different fields of science.

The geochemical analysis of petroleum fractions helps in the evaluation of the type of source rock, quality and thermal maturation of the oil, and the depositional paleoenvironment. Understanding the characteristics of the reservoir fluids has been one of the main factors contributing to successful evaluations and development of oil/gas fields.

The light hydrocarbons (C1 to C5) are the main components of gas in terms of abundance and tend to be in the gaseous state at surface pressure and temperature. Gas chromatography separates gases according to their boiling point. This usually corresponds to the molecular weight; therefore, smaller molecules elute more quickly in the chromatographic column compared to heavier ones.

In consonance with the detailed geochemical analysis, the evaluation of the gases present in the drilling fluid shows that gases unusual in natural contexts are generated during drill bit metamorphism (DBM), including the occurrence of unsaturated gas components, ethene and propylene. The gradual increase in weight on bit (WOB) or rotational speed of the drill (revolution per minute—RPM) is followed by a similar increase in DBM gases generated by the high temperatures and deformation rates experienced at the drill/rock interface.

Advanced Gas (GAV) data are those recorded during drilling, analyzing the composition of the gas released in the drilling fluid and cuttings returned in the process. The molar fractions of Methane to Pentane (C1 to C5) are considered quantitative and, when the data are of good quality, can be correlated with the laboratory gas chromatography analyses, performed on PVT samples. The molar fractions of Hexane to Octane (C6 to C8) and other aromatic components are considered qualitative and should be analyzed with more caution.

PVT data refer to oil samples (including C7+ components) that, within a controlled environment and with the appropriate equipment, are subjected to variations in pressure, volume and temperature, including the injection of other fluids to modify the original state of the product. In this way, it is possible to simulate different conditions to which the oil would be exposed, analyzing the chemical composition and properties of the oil and gas. With PVT analysis, properties such as density, viscosity, saturation, gas/oil ratio, compressibility and shrinkage, among other factors, can be evaluated.

Gas data acquired during the drilling is fundamental to the geological understanding of the operation, and the analyses thereof are vital in the investigation of potential hydrocarbons in the formations. However, a more in-depth analysis of this data is still uncommon and the gas data ends up being underutilized because it is not considered as reliable, nor fully representative of the formation fluids.

The Schlumberger's document Fluid Prediction (available at https://www.slb.com/-online/media/files/drilling/product-sheet/fluid-prediction-ps.ashx, file accessed on Dec. 4, 2023) describes a system that predicts the properties of the reservoir fluids from mud gas data during the drilling of oil wells. It presents a new machine learning-based approach to predict the gas-oil ratio (GOR) using advanced gas (GAV) data.

The method proposed in document EP3789580A1 is a proprietary system called FLAIR, which provides a more precise and quantitative prediction of the properties of the reservoir fluid, particularly the gas-oil ratio (GOR). This system uses advanced gas (GAV) data and ML models based on PVT (Pressure-Volume-Temperature) samples.

The FLAIR unit, short for “Fluid Analysis and Integrated Reporting,” refers to a system involving equipment and software used in the analysis of fluids. FLAIR is composed of several components and steps:
1—Sample Collection: FLAIR collects fluid samples during the drilling process, when the fluid comes into contact with the hydrocarbon formation;
2—Composition Analysis: The collected samples are analyzed to determine the composition of the hydrocarbons present, with a focus on methane (C1), ethane (C2), propane (C3), normal butane (nC4), isomeric butane (iC4), normal pentane (nC5) and isomeric pentane (iC5);
3—Fluid Type Classification: Based on the determined composition, FLAIR classifies the fluid into one of three categories: oil, gas condensate or gas;
4—Use of Classification Models: FLAIR uses machine learning algorithms, such Forest (RF), to classify the fluid type;
5—Data Integration: The analysis results are integrated into a report that provides detailed information about the fluid composition and its type;
6—Real-Time Monitoring: FLAIR operates in real time, allowing the continuous analysis of fluids during the drilling process.

Regarding the ML method, document EP3789580A1 uses a classification algorithm (RF) while the invention uses a regression algorithm (Kernel Ridge). Kernel Ridge is preferred over the RF classifier in multivariate data, when non-linear relations are complex and when there is a need for regularization and greater robustness in data with high dimensionality.

The paper prepared by YANG et al. (YANG, T.; ARIEF, I. H.; HOUBIERS, M.; MEISINGSET, K. K. “A Machine Learning Approach to Predict Gas Oil Ratio on Advanced Mud Gas Data” SPE-195459-MS. 81st Conference and EAGE Exhibition, June 3-6. London, England, 2019) discloses a machine learning model training using a well-established reservoir fluids database with more than 2, 000 PVT samples. After thorough investigation of compositional similarity between reservoir data samples, PVT, and advanced mud and gas data, GAV, the model developed from PVT samples was applied to GAV data.

The proposed method includes the following development steps:
1—Prepare and control the quality of PVT and GAV data;
2—Select and train the machine learning model to predict GOR using a database, based on the C₁-C₅ composition of PVT samples;
3—Investigate the similarity between PVT samples and GAV data to ensure that the GAV data can be used in the machine learning model;
4—Apply the machine learning model trained on PVT samples to the GAV data for GOR prediction;
5—Compare the predicted GOR from the GAV data with GOR measurements from PVT samples to reach conclusions.

Regarding the training targets, the document by YANG et al. uses GOR, while the invention uses the similarity between PVT and GAV. And this proves to be an important difference between this document and the present invention, since YANG et al. used the similarity between PVT and GAV only for the accuracy of the GOR model.

In other words, regarding the training data of the models, the publication by YANG et al. uses the C1-C5 composition of the PVT data, while the invention uses, in addition to PVT, data from GAV, conventional gas, mudlogging (torque, RPM, WOB, MSE), fluids, drill bits and directional data.

Another important point is that YANG et al. did not perform the identification of drill bit metamorphism (DBM).

In view of this, no document of the state of the art discloses a well-defined methodology for developing adherence curves from GAV data such as that of the present disclosure, which exhibits the necessary performance even in wells with total interference from drill bit metamorphism.

In this way, the present disclosure, emphasizing the C2C compound (ethane gas) acquired in the GAV service, is carried out by means of the following steps: a) PVT back analysis, using multivariate statistics to verify the redundant variables and reduce dimensionality, and adopting a similarity analysis approach; and b) applying Machine Learning to build models of adherence curves for the GAV data.

The importance of the user correctly interpreting gas data from drilling was what guided the development of the present invention, which aims at improving the use of mathematical, statistical and computational tools in Geochemistry. The process described herein aims at contributing significantly to the exploratory research.

The referenced disclosure presents advantages, since it now allows greater reliability in the analysis and interpretation of the Gas data, with the display of estimates of associated error or deviation, in addition to simplicity and speed.

### BRIEF DESCRIPTION OF THE DISCLOSURE

The present disclosure addresses to a method of using machine learning to generate adherence curves of the GAV data, involving an analysis by similarities with the PVT analyses, with which it is possible to increase efficiency in decisions and meet the response time required by the operational activities.

The reservoir adherence curve that was intended to be developed in the invention is a model of the expected response for ethane (C2C) acquired in GAV services during the drilling.

In regions where the gas background is low, as well as in portions with high associated drill bit metamorphism (DBM), the curve is expected to present lower values, whereas, in the region corresponding to the reservoir, the expected values for the curve are closer to 1.

An embodiment of a method aims at contributing significantly to the Geochemical research, serving as an instrument for analyzing and interpreting the Gas data. In addition to saving time, there is also reliability in the process, given the use of AI, reducing the great dependence on human resources to obtain the results.

The input data set comprised data from 104 wells containing information on drilling (mudlogging), advanced gas (GAV)—normally obtained by means of GC-MS (Gas Chromatography coupled to Mass Spectrometry)—, conventional gas (GC)—normally obtained by means of GC-FID (Gas Chromatography coupled to Flame Ionization Detector)—, PVT, drill, directional and fluid data.

The initial step of the disclosure is pre-processing, called Quality Control (QC), which includes (i) identifying inconsistencies in the data, missing values (null values) and outliers, (ii) selecting the attributes, and (iii) transforming the units of the variables to the international standard.

Subsequently, a step of exploratory analysis and attribute selection for the back analysis was carried out, which comprises: (i) reducing the dimensionality of the data, (ii) verifying the similarity of the attributes by using the Multidimensional Scaling (MDS) method, (iii) forming clusters using K-Means clustering, and (iv) selecting an attribute from each cluster.

The subsequent step, analyzing similarities of the back analysis, consists of: (i) selecting gas anomalies and classifying the same as reservoir or DBM, (ii) correlating Advanced Gas (GAV) and PVT with depth, (iii) verifying the correlation with the historical base for each curve, identifying patterns in the input data, (iv) estimating the uncertainty factor for the gas curve, enabling an analysis by similarity of the signatures (GAV and PVT), and (v) obtaining deviation and reliability factors.

In order to generate reservoir adherence curves from the similarity analysis, the similarity by correlation based on C2C was then taken as the target.

In the last step, applying Machine Learning, 4 algorithms were tested to create the reservoir adherence curves for gas data acquired during drilling.

Due to the complexity associated with estimating errors and deviations in the Advanced Gas data during the well drilling, it is necessary to use gas and mudlogging parameters (detailed drilling record) to improve the quality of the results. In this way, for the application of machine learning, data from GAV, GC, mudlogging (torque, RPM, WOB and MSE), fluids and drill bits were used.

The Kernel Ridge regression model was the one that proved to be best adjusted to the data set and within expectations, since the adherence curve in the portion where the gas background is low returned low values and, upon entering the reservoir, presented higher values.

The disclosed embodiments are used to reduce the subjectivity of the process and increase the accuracy of the results, which directly affect the costs related to the drilling and well safety, and further in the integration of the gas data recorded in the company, providing greater quality control in the databases.

### BRIEF DESCRIPTION OF THE DRAWINGS

The present disclosure will be detailed below with reference to the attached figures, which comprehensively outline, although not limiting the inventive scope, and present:

FIG. 1: Map of nulls of the mudlogging system acquired during the drilling, according to embodiments of the disclosure;

FIG. 2: Log view of the mudlogging data, according to embodiments of the disclosure;

FIG. 3: Trajectory of the well's directional data, according to embodiments of the disclosure;

FIG. 4: Example of fluid data using the filter options according to embodiments of the disclosure;

FIG. 5: Graph of the drill bit advancement history on the left, and diagram of the drill bit change with the depth on the right, according to embodiments of the disclosure;

FIG. 6: Logs of the most common ratios of the PVT data, according to embodiments of the disclosure;

FIG. 7: Multidimensional Scaling in 2D, according to embodiments of the disclosure

FIG. 8: Illustrative graph of the Elbow Method, according to embodiments of the disclosure;

FIG. 9: K-Means Clustering in 3D, according to embodiments of the disclosure;

FIG. 10: Log containing 5 tracks, from left to right: (1) indication of the PVTs, (2) relation of the PVTs with the selected reservoir and metamorphic intervals, (3) GAV data and intervals, and (4) gas composition with the distribution of the PVTs, according to embodiments of the disclosure;

FIG. 11: Diagram of generation of the similarity analysis graphs, according to embodiments of the disclosure;

FIG. 12: Similarity graphs of the well 8 with C2C—by cosine (above) and by correlation (below), according to embodiments of the disclosure

FIG. 13: Similarity graphs by intervals (reservoir and DBM) for each well with C2C—by cosine (above) and by correlation (below), according to embodiments of the disclosure;

FIG. 14: Similarity graphs by the average of the similarities for each well with C2C—by cosine (above) and by correlation (below), according to embodiments of the disclosure;

FIG. 15: Similarity graphs by lithology for each well with C2C—by cosine (above) and by correlation (below), according to embodiments of the disclosure;

FIG. 16: Adherence curve model proposed by Ridge, according to embodiments of the disclosure;

FIG. 17: Adherence curve model proposed by B-Spline, according to embodiments of the disclosure;

FIG. 18: Adherence curve model proposed by Kernel Ridge, according to embodiments of the disclosure; and

FIG. 19: Adherence curve model proposed by Gradient Boosting Regressor, according to embodiments of the disclosure.

### DETAILED DESCRIPTION OF THE DISCLOSURE

The disclosure relates to a series of pre-processing routines, called QC (Quality Control), which evaluated, validated and organized the imported data to avoid subsequent incoherences in the workflow, in addition to a back analysis step, which statistically explored the data, in order to perform a similarity analysis of the GAV and PVT signatures and, finally, the use of Machine Learning techniques to obtain an adherence curve for the GAV data.

The reservoir adherence curve that was intended to be developed in the invention is a model of the expected response for ethane (C2C) acquired in GAV services during the drilling.

In regions where the gas background is low, as well as in portions with high associated drill bit metamorphism (DBM), the curve is expected to present lower values, whereas, in the region corresponding to the reservoir, the expected values for the curve are closer to 1.

### 1. Input Data

104 wells were used to illustrate the results of the proposed method. These wells present information on drilling (mudlogging), gas advanced (GAV)—normally obtained through GC-MS (Gas Chromatography coupled to Mass Spectrometry)—, conventional gas (GC)—normally obtained through GC-FID (Gas Chromatography coupled to Flame Ionization Detector)—, PVT, drill, directional (or trajectory) and fluid data, which play the role of the predictive attributes. This data set (Table 1) served as input for the subsequent steps of Quality Control and Back analysis, followed by the application of machine learning techniques in the construction of the adherence curve models.

TABLE 1
Input attributes listed by type, (i) Drilling, (ii) Advanced Gas, (iii) Conventional
Gas, (iv) Fluid, (v) Directional, (vi) Drill Bit, and (vii) PVT.

| | |
|---|---|
| DRILLING | ML-PF-ConEnt_mS/cm, ML-PF-WOB t, ML-PF- |
| | CHKPRS_kgf/cm², ML-PF-SPP kgf/cm², ML- |
| | PF-TEnt_degC., ML-PF-TSai_degC., ML-PF- |
| | ROP_min/mx, ML-PF-DSai_g/cm3, ML-PF- |
| | MDLAG_m, ML-PF-TBFE_h, ML-PF-H2S ppm, |
| | ML-PF-RPM rpm, ML-PF-TORQUE Ibfft, ML- |
| | PF-FLWIN 1/min, ML-PF-ConSai_mS/cm, ML- |
| | PF-VSai_l/min, ML-PF-DEnt_g/cm3, ML-PF- |
| | TOTVOL_m3, ML-PF-TC_ugp |
| ADVANCED GAS | ML-GA-BZ_ppm, ML-GA-BZIN_ppm, ML-GA- |
| (GAV) | BZOUT ppm, ML-GA-CO2 ppm MLGA-C2 ppm, |
| | ML-GA-C20 ppm, ML-GA-C2CEEC ppm, ML-GA- |
| | C2CIN ppm, ML-GA-C2COUT ppm, ML GA-C2IN |
| | ppm, ML-GA-C2OUT_ppm, ML-GA-C7 ppm, ML- |
| | GA-C7IN ppm, ML-GA-C7OUT_ppm, ML-GA-C6 |
| | ppm, ML-GA-C6IN ppm, ML-GA-C6OUT_ppm, |
| | ML-GA-IC4 ppm, MI-GA-IC4EEC ppm, ML-GA- |
| | IC4IN ppm, ML-GA-IC4OUT ppm, ML-GA-IC5 |
| | ppm, ML-GA-ICSEEC ppm, ML-GA-ICSIN ppm, |
| | ML-GA-ICSOUT_ppm, ML-GA-C1 ppm, ML-GA- |
| | C1EEC ppm, ML-GA-C1IN_ppm, ML-GA-NC4 |
| | ppm, ML-GA-C1OUT ppm, ML-GA-NC4OUT ppm, |
| | ML-GA-NCAIN_ppm, ML-GA-NC5 ppm, ML-GA- |
| | NC5EEC ppm, ML-GA-NC4EEC ppm, ML-GA-C8 |
| | ppm, ML-GA-NC5OUT ppm, ML-GA-C8IN_ppm, |
| | ML-GA-C8OUT ppm, ML-GA-NCSIN_ppm, ML- |
| | GA-C2EEC ppm, ML-GA-C3 ppm, ML-GA-C3EEC |
| | ppm, ML GA-C3IN ppm, MEGA-C3OUT ppm, ML- |
| | GA-CO2IN_ppm, ML-GA-CO2OUT ppm |
| CONVENTIONAL GAS | POCO, DEPTH_m, ML-GC-TGAS_ppm, ML-GC- |
| (GC) | TGAS_ugt, ML-GC-C1_ppm, ML-GC-C2_ppm, |
| | ML-GC-C3_ppm, ML-GC-IC4_ppm, ML-GC- |
| | NC4_ppm, ML-GC-IC5_ppm, ML-GC-NC5_ppm, |
| | ML-GC-C5_ppm, ML-GC-CO2_ppm, ML-GC- |
| | CO2Med_ppm, ML-GC-CO2LIN_ppm, ML-GC- |
| | H2S_ppm, ML-GC-H2SMed_ppm, ML-GC- |
| | H2SLIN_ppm, ML-GC-MWOUT_lb/gal, ML-GC- |
| | MWIN_lb/gal, ML-GC-CNDOUT_mS/cm, ML-GC- |
| | CNDIN_mS/cm, ML-GC-TMPOUT_degC., ML-GC- |
| | TMPIN_degC., ML-GC-TCMed_ppm, ML-GC- |
| | TCMax_ppm, ML-GC-TCMax_ugt, ML-GC- |
| | C6_ppm, ML-GC-C7_ppm, ML-GC-C8_ppm, ML- |
| | GC-CO2Max_ppm, ML-GC-H2SMax_ppm, ML-GC- |
| | DMax_g/cm3, ML-GC-DMin_g/cm3, ML-GC- |
| | ConMax_mS/cm, ML-GC-ConMin_mS/cm, ML- |
| | GC-TMax_degC., ML-GC-TMin_degC. |
| FLUID | DATA_HORA_COLETA, DATA_COLETA |
| | HORA_COLETA, POCO, BASE_FLUIDO, FASE, |
| | PROF_COLETA, LOCAL_COLETA, FLUIDO, |
| | DENSIDADE, GEL_10_SEG, GEL_10_MIN, |
| | GEL_30_MIN, FILTRADO_API, |
| | TEMP_FLOW_LINE, FILTRADO_ATAP, |
| | TEMP_TESTE_FILTRACAO, BARITA, |
| | FLUIDO_TROCADO, TEMP_TESTE_FLUIDO, PM, |
| | PF, CALCIO, TEOR_AGUA, TEOR_OLEO, |
| | RAZAO_OLEO, RAZAO_AGUA, LIM_ESCOAMENTO, |
| | ESTABILIDADE_ELETRICA, |
| | VISCOSIDADE_PLASTICA, NACL, KCI, CACL2, |
| | CLORETOS, PH, VISCOSIDADE_MARSH |
| DIRECTIONAL | POCO, MD, INCLINACAO, AZIMUTE |
| DRILL BIT | CODUTILIZ, NOSERIE, CODMODELO, MODELO, |
| | CABO_TX_TIPO_BROCA, IADC, IADCBR, |
| | ENTRADA_INICIAL, ENTRADA_FINAL, |
| | DT_ENTRADA, DT_SAIDA, METRAGEM, TBF, |
| | EQCODL, EQ, SEQ, DIAMBROCA, DIAMFASE, |
| | TFA, DESGASTEOFICIAL, DESGASTEOCORRIDO, |
| | MOTIVO, MOTIVORETIRADA, POCO |
| PVT | Fluid, POCO, Top (m), Bottom (m), |
| | Bottle, Certificate, Type, H2S |
| | content(ppmv), RGO, API, N2, CO2, C1, |
| | C2, C3, IC4, NC4, IC5, NC5, C6, C7, C8, |
| | C9, C10, C11, C12, C13, C14, C15, C16, |
| | C17, C18, C19, C20+, MCICLOC5, BENZENE, |
| | CICLO-C6, MCICLOC6, TOLUENO, C2BENZEN, |
| | MPXILENO, O-XILENO, NC6, NC7, NC8, NC9, |
| | Total Molar Mass |

TABLE 2
List of the most common acronyms in the attribute nomenclatures.

| | |
|---|---|
| ML | Mudlogging |
| PF | Drilling |
| GA | Advanced Gas |
| GC | Conventional Gas |
| WOB | Weight on the bit |
| ROP | Drilling rate |
| RPM | Revolutions per minute |
| DEPTH | Depth |
| NACL | Salinity |
| DIAMBROCA | Drill bit diameter |
| FLWOUT | Output flow |
| FLWIN | Input flow |
| ppm | Unit of measurement (parts per million) |
| C1-C5 | Molar fractions of Methane to Pentane |
| C6-C8 | Molar fractions of Hexane to Octane |

### 2. Quality Control (QC)

The drilling environment can significantly influence the reading of gas data. Accordingly, performing quality control (QC) procedures is essential to minimize the risk of errors in the analyses/interpretations.

The so-called QC includes tasks such as (i) identifying inconsistencies in the data, as well as null values (rows and columns with missing values) and outliers (anomalous compositional data), (ii) selecting the attributes, and (iii) transforming the units of the variables to international standards, which factors that make this pre-processing step necessary.

The initial data processing phase allowed for cleaning and optimization of the data table, with the discovery of classification errors, sample identification errors, recognition of duplicate records, naming errors and elimination of outliers.

For a more dynamic approach to the information and in order to make the quality control (QC) step feasible, methods for viewing and editing the well data were implemented. These data include drilling (mudlogging, GC and GAV), drills, trajectory (or directional), fluids and PVT. This processing also allows the export of the filtered data, which is crucial in the next steps of the work.

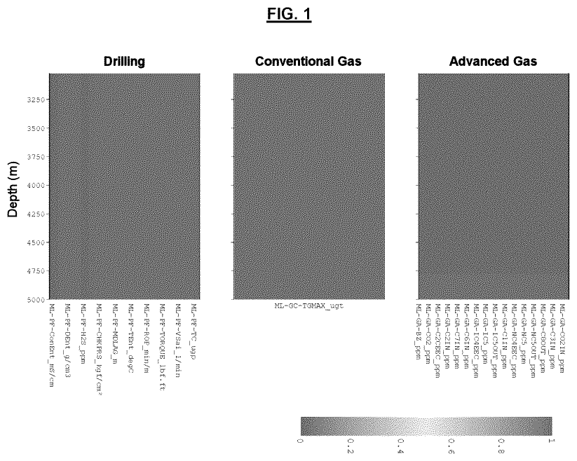

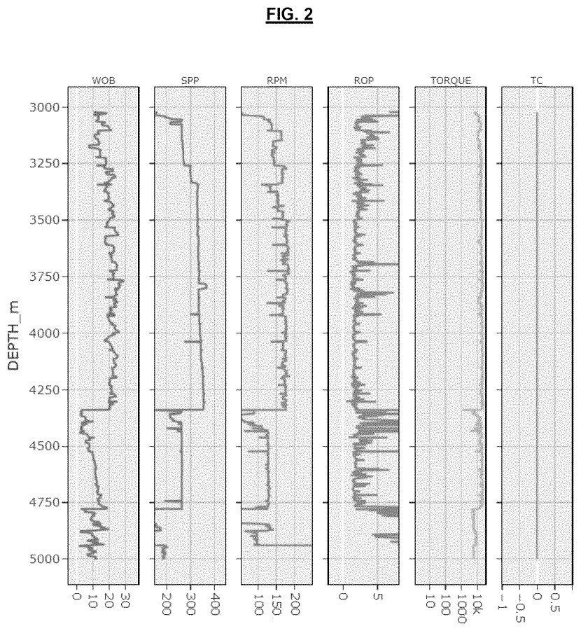

The records of the drilling data acquisition system are shown from the null map (FIG. 1) to the logging view of the mudlogging data (FIG. 2), GC and GAV.

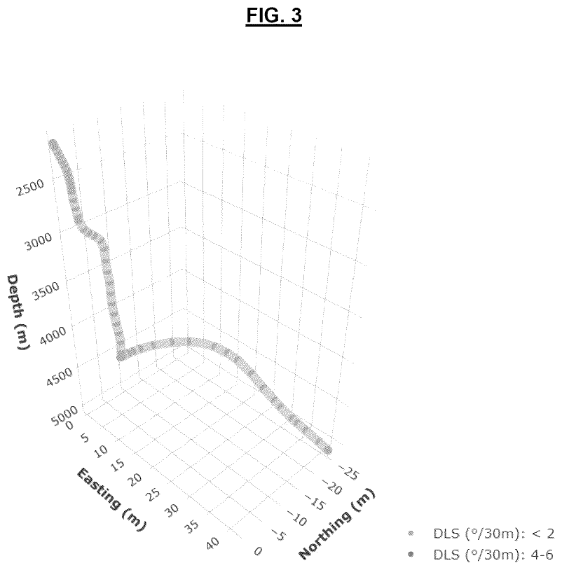

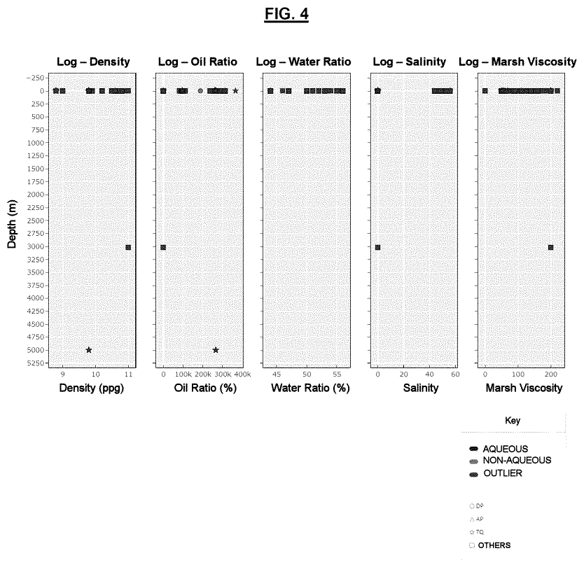

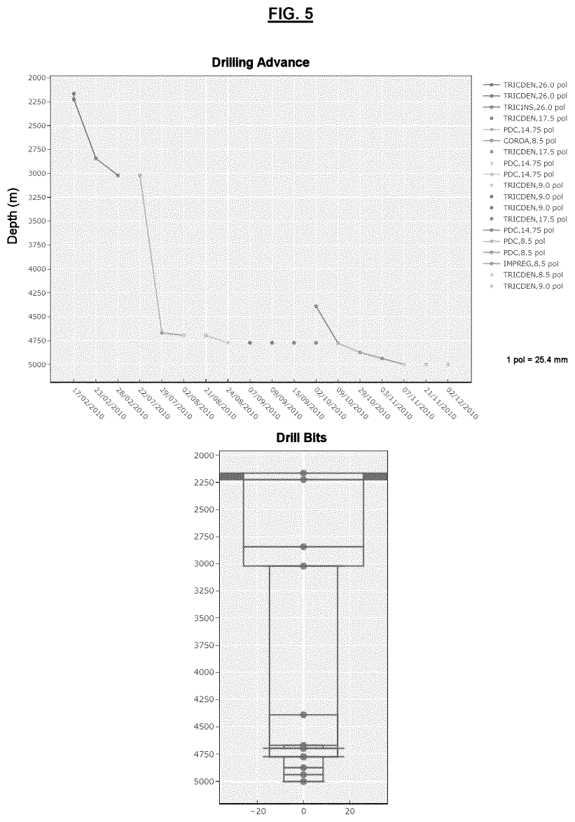

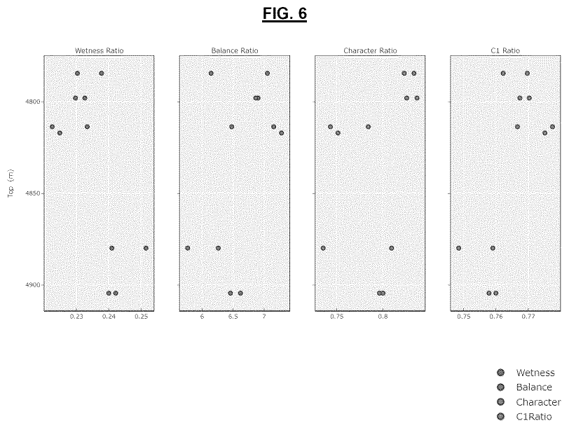

FIG. 3 shows the trajectory records and, in FIG. 4, there are the well fluid data. In FIG. 5, one can see the history of the drill bit advance during the drilling, as well as the diagram of the drill bit change with the depth. FIG. 6 shows the PVT records, including the logs of the most common ratios (wetness, balance, character and C1).

### 3. Back Analysis—Exploratory Analysis and Attribute Selection

The EDA (Exploratory Data Analysis) step is extremely important in the back analysis process. To understand the statistical properties of the data, highlighting the presence of attributes that are not very explanatory and are redundant, procedures can be performed such as (i) reducing the dimensionality of the data, (ii) checking the similarity of the attributes by using the Multidimensional Scaling (MDS) method, (iii) identifying the ideal number of clusters that the attributes can form, applying the Elbow method, (iv) forming clusters using K-Means clustering.

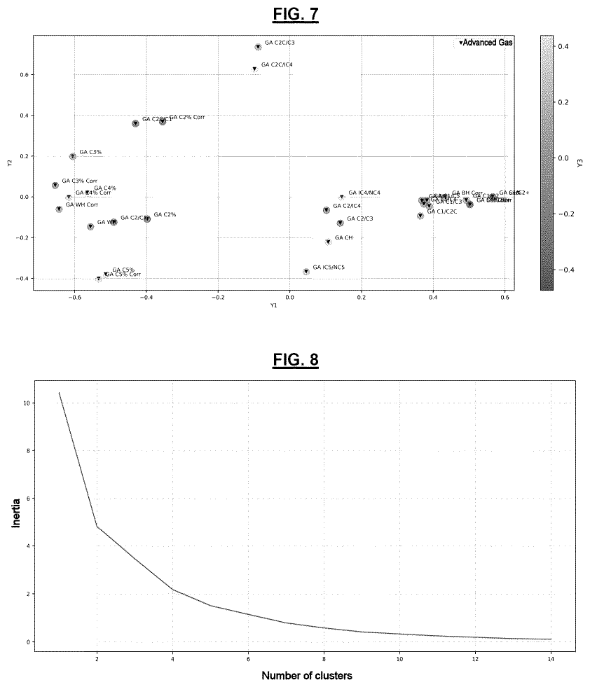

The Multidimensional Scaling measures the degree of similarity or dissimilarity in multivariate structures. The correlation between the variables is used as a basis for calculating the distance matrix; the greater the distance, the greater the dissimilarity, so that the grouped variables are highly correlated, presenting high similarity and smaller distances between them. FIG. 7, representing the MDS, shows the 2D view, wherein the third axis, the depth, corresponds to the applied colors.

The Elbow method determines the “optimal” number of clusters. From the value indicated by the “elbow” in the graph, it means that there is no gain in relation to the increase in clusters. In FIG. 8, it can be seen that 3 to 6 is an appropriate number of groups to work with.

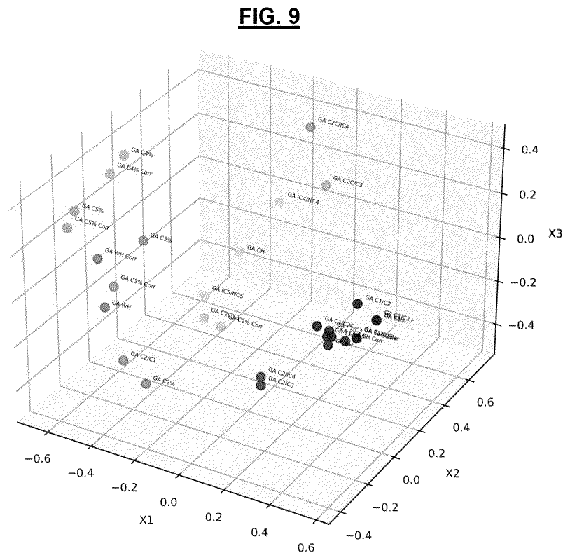

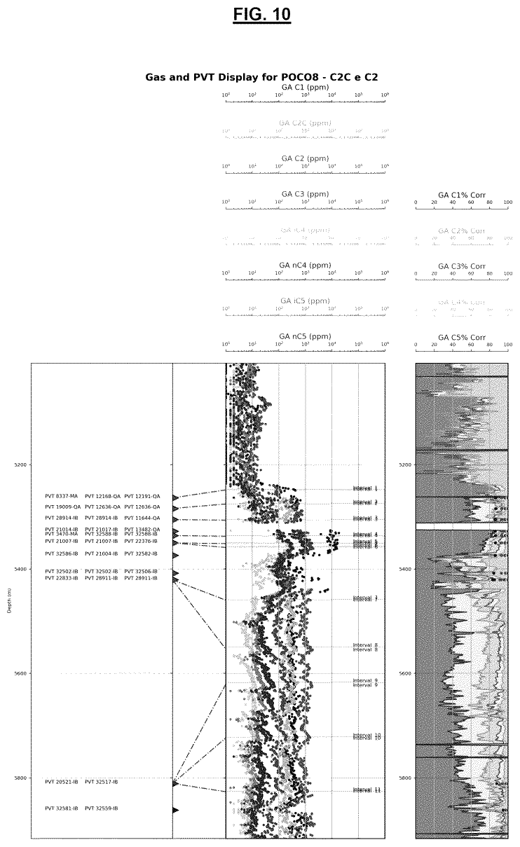

The K-Means Clustering is an optimization technique for separating data into clusters. The center of each group (centroid) is the arithmetic mean of all the points that belong to the same. The number of groups K is defined in advance, and then each data is assigned to the centroid closest to it, starting the iterations, which end when the variables no longer change their cluster centers. The centroids move their positions until the convergence criteria have been met. FIG. 9 shows the 3D view of the K-Means clustering for the data set of this project.

To proceed with the selection of the attributes with the groups formed, a feature was chosen within each cluster.

It is important to note that this set of attributes served as a basis only for Step III, similarity analysis; in Step IV, Machine Learning, all variables available after the quality control (Step I) were used.

### 4. Back Analysis—Similarity Analysis

To produce the PVT back analysis, it is necessary to carry out a series of activities that include, (i) selecting gas anomalies and classifying them as reservoir or DBM, (ii) correlating Advanced Gas (GAV) and PVT with depth, (iii) analysis by similarity of signatures (GAV and PVT).

For the signature similarity analysis step, the following attributes were used, categorized by type: (i) GAV data: POCO, DEPTH m, ML-GA-C1 ppm, ML-GA-C2 ppm, ML-GA-C2C ppm, ML-GA-C3 ppm, ML-GA-IC4_ppm, ML-GA-NC4_ppm, ML-GA-IC5_ppm, ML-GA-NC5_ppm, (ii) PVT data: Top, Base, Fluid, Bottle, Type, C1, C2, C3, IC4, NC4, IC5, NC5, and (iii) complementary features: Depth, Gas, Lithofacies, Type, Quality.

The compounds relevant to the study comprise simple mathematical operations between the hydrocarbons, as listed in Table 3.

TABLE 3
Mathematical operations between the hydrocarbons that
result in the compounds relevant to the study.

| HYDROCARBON | | |
|---|---|---|
| CONTENT | PERCENTAGES | RATIOS |
| sumHC = (C1 + | C1% = (C1/sumHC) * 100 | C1/C2 = (C1/(C1 + C2)) * 100 |
| C2 + C3 + | C2% = (C2/sumHC) * 100 | C1/C3 = (C1/(C1 + C3)) * 100 |
| IC4 + NC4 + | C3% = (C3/sumHC) * 100 | C1/C4 = (C1/(C1 + C4)) * 100 |
| IC5 + NC5) | C4% = ((IC4 + NC4)/sumHC) | C1/C2+ = (C1/(sumHC − |
| | * 100 | C1)) * 100 |
| | C5% = ((IC5 + NC5)/sumHC) | C2/C1 = (C2/(C1 + C2)) |
| | * 100 | * 100 |
| | | C2/C3 = (C2/(C2 + C3)) |
| | | * 100 |
| | | C2/IC4 = (C2/(C2 + |
| | | IC4)) * 100 |
| | | IC4/NC4 = (IC4/(IC4 + |
| | | NC4)) * 100 |
| | | IC5/NC5 = (IC5/(IC5 + |
| | | NC5)) * 100 |
| | | Sec = (C1/sumHC) * 100 |
| | | WH = ((C2 + C3 + C4 + C5)/sumHC) |
| | | * 100 |
| | | BH = ((C1 + C2)/sumHC) |
| | | * 100 |
| | | CH = ((C4 + C5)/(C3 + |
| | | C4 + C5)) * 100 |

FIG. 10 shows the GAV and HC composition logs, with the distribution of the PVTs and the selected reservoir and metamorphic intervals.

To qualify the back analysis, two similarity measures were used, cosine and correlation, taking into account the selected intervals and the closest PVT data for each interval in a given well, in order to evaluate which would present the best performance with the work data set.

The cosine similarity is that made between two value vectors that evaluates the cosine of the angle formed by the same, providing a similarity between [0, 1]. The correlation similarity (Pearson's linear) indicates the relation between two linear variables in an interval of [-1, 1] (the correlation can be positive or negative); the closer to zero, the lower the similarity.

Based on these analyses, graphs were generated. FIG. 11 outlines the methodology, containing the similarity analyses for C2C, by cosine and correlation, in a specific well and multiwells. In the multiwell graphs, the similarities by reservoir and DBM intervals were also verified, by the average of these similarities per well and by lithology considering only the DBM samples.

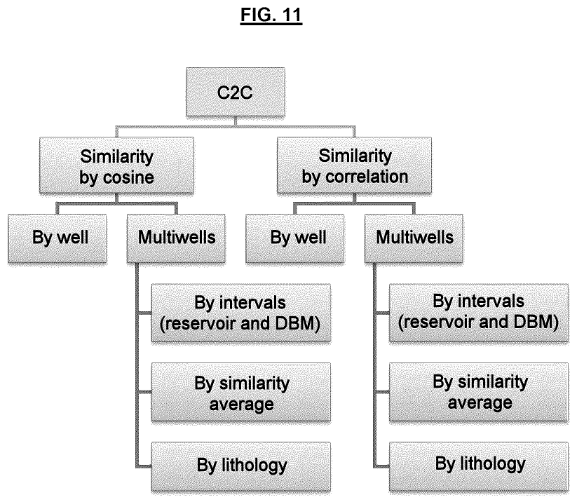

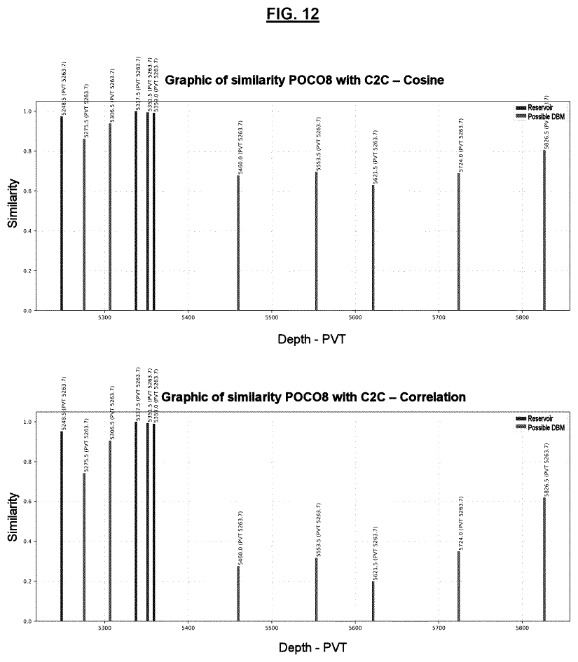

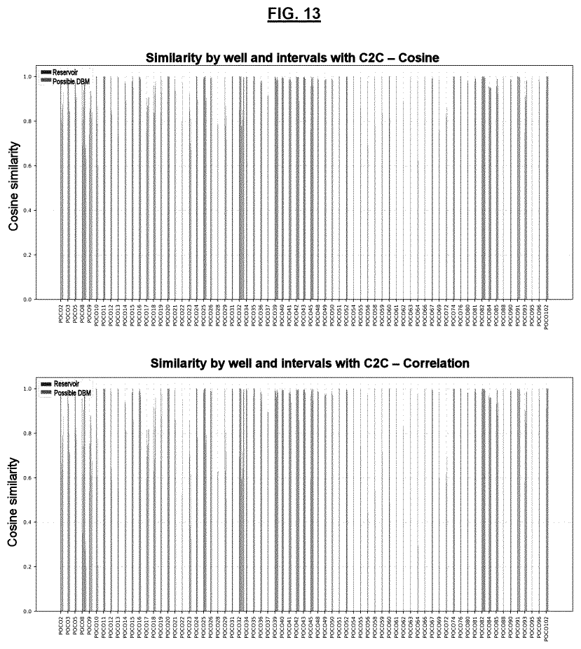

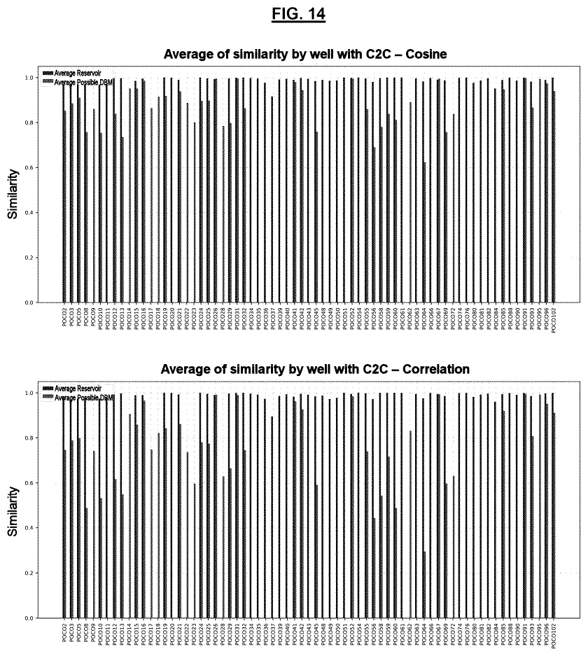

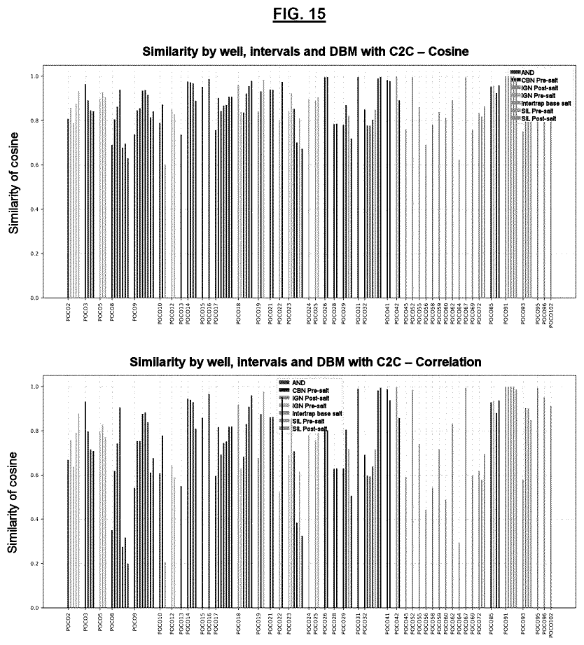

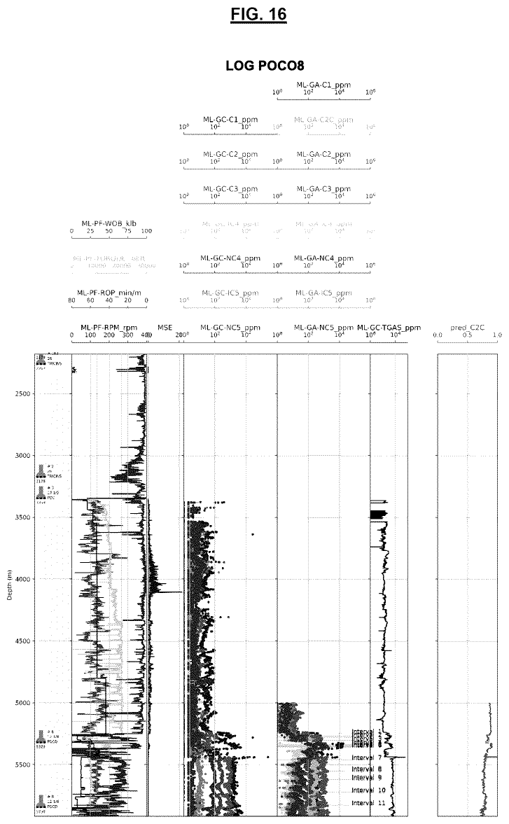

FIG. 12 presents the similarity graphs for a specific well, highlighting well 8, which proved to be quite didactic, encompassing several operational conditions. FIG. 13 presents the multiwell similarity graphs by intervals (reservoir and DBM). FIG. 14 presents the multiwell similarity graphs by the average of the similarities and, concluding this step, FIG. 15 presents the multiwell similarity graphs by lithology (DBM).

Regarding the analysis of similarities by well, the particularity of well 8 is related to the fact that it encompasses all environments, including: (i) post-salt, with low gas, (ii) basal anhydrite, where the drill bit metamorphism increases right at the entrance, and (iii) reservoir, which starts without the drill bit metamorphism and then presents the same. The multiwell similarities by intervals and by average disclosed that there is no uniform response pattern, ranging from wells without drill bit metamorphism to wells with metamorphism throughout their extension. The analysis by lithology allowed to observe, for example, the types of rock that present more or less drill bit metamorphism.

It can be concluded from this step that the similarity by correlation proved to be more assertive; in the intervals with severe drill metamorphism, the similarity in relation to the PVT was shown to be low (less than that of the cosine) and, in the reservoir intervals, the similarity in relation to the PVT was shown to be high (greater than that of the cosine).

### 5. Supervised Classification

In order to generate reservoir adherence curves from the similarity analysis, the similarity by correlation based on C2C was chosen as the target.

For the application of the machine learning in the study, a data set was selected, including: ‘ML-PF-ROP_min/m’, ‘ML-PF-TORQUE_lbf.ft’, ‘ML-PF-RPM_rpm’, ‘ML-PF-WOB_klb’, ‘ML-PF-FLWOUT_%’, ‘ML-GC-C1 ppm’, ‘ML-GC-C2 ppm’, ‘ML-GC-C3_ppm’, ‘ML-GC-IC4_ppm’, ‘ML-GC-NC4_ppm’, ‘ML-GC-IC5_ppm’, ‘ML-GC-NC5_ppm’, ‘ML-GC-TGAS_ppm’, ‘ML-GA-C1_ppm’, ‘ML-GA-C2_ppm’, ‘ML-GA-C2C_ppm’, ‘ML-GA-C3_ppm’, ‘ML-GA-IC4_ppm’, ‘ML-GA-NC4_ppm’, ‘ML-GA-IC5_ppm’, ‘ML-GA-NC5_ppm’, ‘DIAMBROCA’, ‘CODMODELO_enc’, ‘FLUIDO_enc’, ‘DENSIDADE’ ‘RAZAO_OLEO’, ‘RAZAO_AGUA’, ‘NACL’, ‘VISCOSIDADE_MARSH’, ‘MSE’.

The methods used in the Machine Learning step included: Ridge, Kernel Ridge, B-Spline, Gradient Boosting Regressor, with the objective of generating different models to verify those that would fit better, more accurately, to the data.

For training and testing, 80% and 20% of the total samples were applied, respectively. And to evaluate the regression models, two performance indicators were used, RMSE and R-Squared.

RMSE (Root Mean Square Error) is a measure of the average difference between the values predicted by a model and the actual values, which also provides an estimate of how well the model is able to predict the target value (precision); the lower the value, the better; a perfect model would have an RMSE equal to 0.

R-Squared (or coefficient of determination), in turn, is a statistical measure that indicates how much of the variance of a dependent variable can be explained by an independent variable. In other words, R-Squared shows the quality of the fit, that is, how well the data fits the regression model; the closer to 1, the better the fit of the data to the model.

### 5.1. Ridge

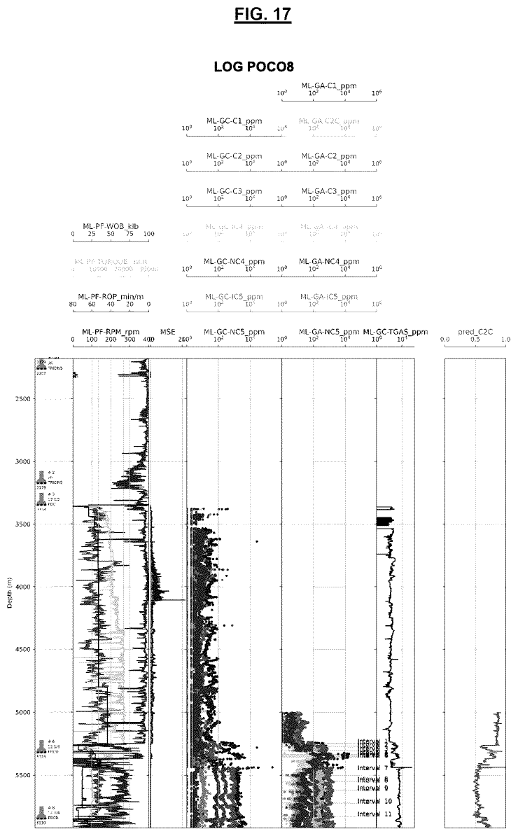

The model proposed by Ridge, shown in FIG. 16, is not compatible with the similarity data, not showing much contrast in reservoir zones (values where the gas background is low are also with high values), nor in zones with extreme drill bit metamorphism (values are also high).

Table 4 presents the R-Squared and RMSE performance indicators for the method.

TABLE 4
Performance of the ML algorithms based
on R-Squared and RMSE indicators.

| Algorithm | R-squared | RMSE |
|---|---|---|
| Ridge | 0.60 | 0.20 |
| B-Spline | 0.85 | 0.12 |
| Kernel Ridge | 0.89 | 0.09 |
| Gradient Boosting Regressor | 0.97 | 0.057 |

In terms of feature importance, the three most important were: advanced gas (methane and ethane) drilling fluid (density).

### 5.2. B-Spline

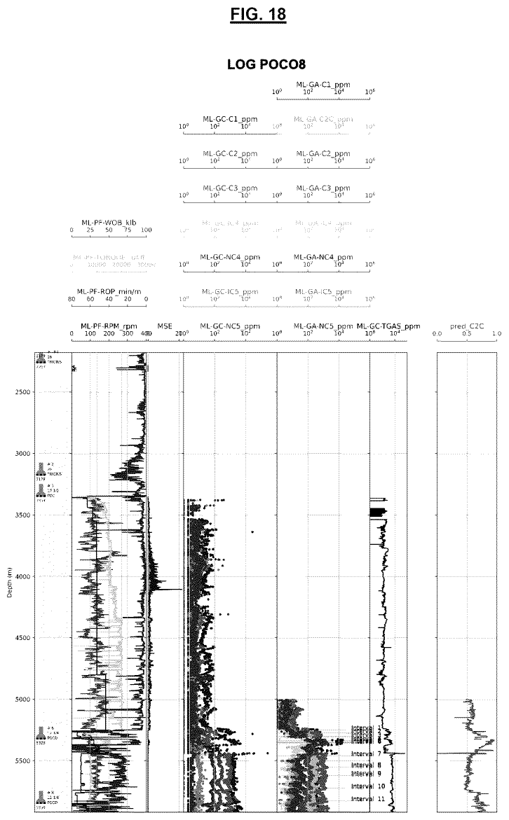

The resulting adherence curve of the B-Spline method, FIG. 17, does not comply with what was expected; in the initial portion of the curve, where it is known that the gas background is low, the values are very high.

Table 4 presents the R-Squared and RMSE performance indicators for the method.

In terms of feature importance, the three most important were: conventional gas (butane), drilling fluid (fluid type) and advanced gas (methane).

### 5.3. Kernel Ridge

In the Kernel Ridge model, illustrated in FIG. 18, in the shallower initial part, where the gas background is low, the curve presented, as expected, lower values. In the reservoir region, the curve values were higher, which was also expected. In the following portion, with severe drill bit metamorphism, the values decreased, as expected. At greater depth, an anomalous behavior occurred in the adherence curve, with higher values in the final portion, but this was not considered detrimental to its performance as a whole.

Table 4 presents the R-Squared and RMSE performance indicators for the method.

In terms of feature importance, the three most important were: advanced gas (ethane+ethylene, methane and ethane) were the most important.

### 5.4. Gradient Boosting Regressor

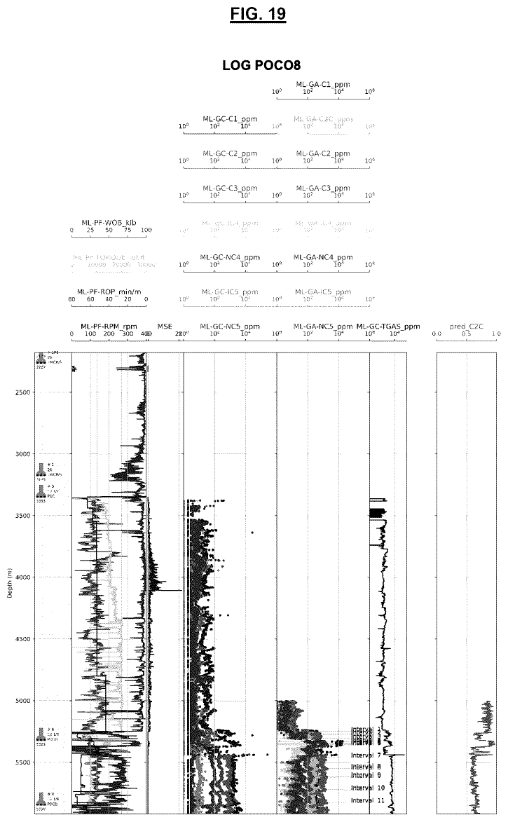

The Gradient Boosting Regressor method, FIG. 19, presented very high values of C2C adherence in the initial portion of the curve, where the gas background is very low, making the model without great affinity with this data set, although, in the reservoir and high DBM portions, the curve behaved as expected.

Table 4 presents the R-Squared and RMSE performance indicators for the method.

In terms of feature importance, the three most important were: drilling (penetration rate) and advanced gas (methane and ethane+ethylene) are the three most important.

### 5.5. Discussion of Results

The model obtained by the Kernel Ridge algorithm proved to be, in its entirety, better adjusted to the data set and with results closer to expectations; in second place, there is Gradient Boosting Regressor.

Regarding the performance indicators, the models performed in this order: Gradient Boosting Regressor, Kernel Ridge, B-Spline and Ridge. This analysis, in a way, is in line with the models most compatible with the presented data set.

Regarding the features that most influenced the generation of the proposed curve, the advanced gas attributes (methane-four times present, ethane+ethylene and ethane-twice each) were the most recurrent among the three most important.

### 6. Application and Validation of the Models

The reservoir adherence curve that was intended to be developed in the invention is a model of the expected response for ethane (C2C) acquired in GAV services during the drilling.

In regions where the gas background is low, as well as in portions with high associated drill bit metamorphism, the curve was expected to present lower values, whereas, in the region corresponding to the reservoir, the expected values for the curve are closer to 1.

Four models were then suggested for the adherence curve: Ridge, B-Spline, Kernel Ridge and Gradient Boosting Regressor. The choice between the models to be applied to a new data set will depend on the characteristics of the data.

The Ridge regression is useful for preventing overfitting in linear models, while B-Spline, Kernel Ridge and Gradient Boosting Regressor are more suitable for modeling non-linear relations. Therefore, the selection of the most appropriate model will depend on the complexity of the problem in question.

Those skilled in the art will value the knowledge presented herein and will be able to reproduce the invention in the embodiments presented and in other variants, encompassed by the scope of the attached claims.

1. A method for creating adherence curve models from gas data acquired during drilling by use of machine learning, the method comprising the following steps:
1. controlling quality by:
1.1) evaluation, validation and organization of the imported data set of wells containing drilling information (mudlogging), advanced gas (GAV), conventional gas (GC), PVT, drill, directional and fluid data;
1.2) viewing and editing of data and exporting of filtered data;
2. performing background analysis—for Exploratory Analysis and Attribute Selection by:
2.1) investigation of the statistical properties of the data by reducing the dimensionality of the data, checking the similarity of the attributes using the Multidimensional Scaling method, identifying the ideal number of clusters that the attributes can form, applying the Elbow method, and forming clusters using the K-Means technique;
2.2) selection of the subset of attributes for the similarity analysis, carried out by choosing one attribute from each cluster;
3) performing background analysis—for Similarity Analysis by:
3.1) (i) select gas anomalies and classify the same as reservoir or DBM, (ii) correlate Advanced Gas (GAV) and PVT with depth, and (iii) analysis by similarity of the signatures (GAV and PVT);
3.2) similarity by cosine and correlation;
4. conducting Supervised Classification by:
4.1) use of machine learning algorithms to generate reservoir adherence curves based on C2C;
4.2) methods: Ridge, Kernel Ridge, B-Spline, Gradient Boosting Regressor;
4.3) the performance of the models is evaluated by the RMSE and R-Squared indicators; and
5. applying and validating of Reservoir Adherence Curves by:
5.1) selection of models and use in new sample sets.

2. The method according to claim 1, wherein in step 1, data preprocessing occurs:
a) rows and columns with missing values are removed or replaced;
b) inconsistent data are eliminated;
c) outliers are removed.

3. The method according to claim 1, wherein in step 1, the visualization and editing of well data was applied to the set of CQ processes:
a) Wells: general information about each well;
b) Drilling data: visualization of mudlogging, GC and GAV data;
c) Trajectory: directional data in 3D graph;
d) Fluids: fluid data in logs (section of filters to be applied);
e) Drills: drill data in graphs (advance history and drill change scheme);
f) PVT: PVT data in logs (chosen attributes and reasons).

4. The method according to claim 1, wherein in step 2, the normalization of numerical features occurs.

5. The method according to claim 1, wherein in step 2, the Exploratory Data Analysis occurs by using the methods:
a) multidimensional scaling;
b) Elbow method;
c) K-Means method.

6. The method according to claim 1, wherein in step 3, the Similarity Analysis by cosine and Pearson's linear correlation occurs.

7. The method according to claim 1, wherein in step 4, the performance of the machine learning algorithms is evaluated by using the indicators: root mean square error and R-squared.
